(19) United States
(12) Patent Application Publication
(10) Pub. No.: US 2026/0271800 A1
(43) Pub. Date: Sep. 10, 2026

(54) ELECTRONIC PACKAGE HAVING A DIE WITH ENDCAP STRUCTURES

(71) Applicant: QUALCOMM Incorporated, San Diego, CA (US)

(72) Inventors: Aniket PATIL, San Diego, CA (US); Manuel ALDRETE, Encinitas, CA (US); Piyush GUPTA, San Diego, CA (US)

(21) Appl. No.: 19/072,722

(22) Filed: Mar. 6, 2025

(51) Int. Cl. H01L 23/498; H01L 21/48; H01L 23/00; H01L 23/538; H01L 25/16; H10B 80/00; H10D 80/30

(52) U.S. Cl. CPC H10W 90/701; H10B 80/00; H10D 80/30; H10W 70/093; H10W 70/611; H10W 70/65; H10W 90/00; H10W 90/401; H10W 72/823; H10W 90/724; H10W 90/754

(57) ABSTRACT

In an aspect, an electronic package is disclosed that comprises comprising a system-on-chip (SOC) die having a first set of metallization structures and a keep-out-zone (KOZ) separating the first set of metallization structures from an edge of the SOC die. An endcap structure is disposed at the edge of the SOC die. The endcap structure includes a dielectric layer extending about and in contact with at least a portion of the edge of the SOC die and into the KOZ, and a metal layer disposed exterior to the dielectric layer. A lower substrate has a second set of metallization structures electrically connected to the first set of metallization structures and to the metal layer of the endcap structure. An upper substrate overlies the SOC die and includes a third set of metallization structures electrically connected to the metal layer of the endcap structure.

### FIELD OF DISCLOSURE

The present disclosure generally relates to electronic packaging and, more particularly, to an electronic package having a die with endcap structures.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system-on-chip (SOC) devices, which may include multiple function blocks, with each function block designed to perform a specific function, such as, for example, a microprocessor function, a graphics processing unit (GPU) function, a communications function (e.g., WiFi, Bluetooth, and other communications), and the like.

In advanced electronic packaging, package miniaturization has become desirable due to the growing need for compact, high-performance devices in consumer electronics, automotive systems, and medical technologies. Modern applications, such as smartphones, wearables, and Internet of Things (IoT) devices, require increasingly smaller form factors while maintaining or enhancing functionality. The increasingly smaller form factors and enhanced functionality give rise to a need for high-density integration of the components in such applications to incorporate multiple features, such as processing, storage, and connectivity, within a single package or a reduced number of small modules that may be integrated into smaller packaging units.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an electronic device includes an electronic package comprising a system-on-chip (SOC) die having a first set of metallization structures on at least one surface thereof and a keep out zone (KOZ) separating the first set of metallization structures from an edge of the SOC die; at least one endcap structure disposed at the edge of the SOC die, the endcap structure including a dielectric layer extending about and in contact with at least a portion of the edge of the SOC die and into the KOZ, and a metal layer disposed exterior to the dielectric layer; a lower substrate having a second set of metallization structures electrically connected to the first set of metallization structures and to the metal layer of the at least one endcap structure; and an upper substrate overlying the SOC die and having a third set of metallization structures electrically connected to the metal layer of the at least one endcap structure.

In an aspect, an electronic package includes a system-on-chip (SOC) die having a first set of metallization structures on at least one surface thereof and a keep out zone (KOZ) separating the first set of metallization structures from an edge of the SOC die; at least one endcap structure disposed at the edge of the SOC die, the endcap structure including a dielectric layer extending about and in contact with at least a portion of the edge of the SOC die and into the KOZ, and a metal layer disposed exterior to the dielectric layer; a lower substrate having a second set of metallization structures electrically connected to the first set of metallization structures and to the metal layer of the at least one endcap structure; and an upper substrate overlying the SOC die and having a third set of metallization structures electrically connected to the metal layer of the at least one endcap structure.

In an aspect, a method of fabricating an electronic package includes receiving a system-on-chip (SOC) die having a first set of metallization structures on at least one surface thereof and a keep out zone (KOZ) separating the first set of metallization structures from an edge of the SOC die; forming at least one endcap structure disposed at the edge of the SOC die, the endcap structure including a dielectric layer extending about and in contact with at least a portion of the edge of the SOC die and into the KOZ, and a metal layer disposed exterior to the dielectric layer; connecting a lower substrate having a second set of metallization structures to the first set of metallization structures and to the metal layer of the at least one endcap structure; and overlying the SOC die with an upper substrate and connecting a third set of metallization structures of the upper substrate to the metal layer of the at least one endcap structure.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, which are presented solely for illustration and not limitation of the disclosure.

FIG. 1 is a cross-sectional view of an example package-on-package (POP) assembly, according to aspects of the disclosure.

FIG. 2A is a cross-sectional view of a package-on-package assembly, according to aspects of the disclosure.

FIG. 2B is a cross-sectional view showing an example endcap structure at an outer edge of a system-on-chip (SOC) die, according to aspects of the disclosure.

FIG. 3 and FIG. 4 show example engagements between endcap structures and external edges of a die, according to aspects of the disclosure.

FIG. 5A through FIG. 5G show example operations that may be employed in fabricating a package-on-package assembly that includes an electronic package, according to aspects of the disclosure.

FIG. 6 shows an example arrangement in which endcap structures are electrically connected to contacts at the outer edges of a die, according to aspects of the disclosure.

FIG. 7 shows another example arrangement in which endcap structures are electrically connected to contacts at the outer edges of a die, according to aspects of the disclosure.

FIG. 8 shows an example method that may be used to fabricate an electronic package, according to aspects of the disclosure.

FIG. 9 illustrates a profile view of a package that includes a surface mount substrate, an integrated device, and an integrated passive device, according to aspects of the disclosure.

FIG. 10 illustrates an example method for providing or fabricating a package that includes an integrated device comprising a power splitter, according to aspects of the disclosure.

FIG. 11 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC).

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

As used herein, the term “contact” refers to any conductive element designed to establish an electrical connection, including: 1) pads, 2) pins, 3) bumps, or 4) any combination of such elements. As used herein, the term “metallization structure” refers to the patterned metallization layers, the metalized vias, and the contacts formed in a substrate that are configured to electrically connect the electrical components mounted on or in the substrate.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

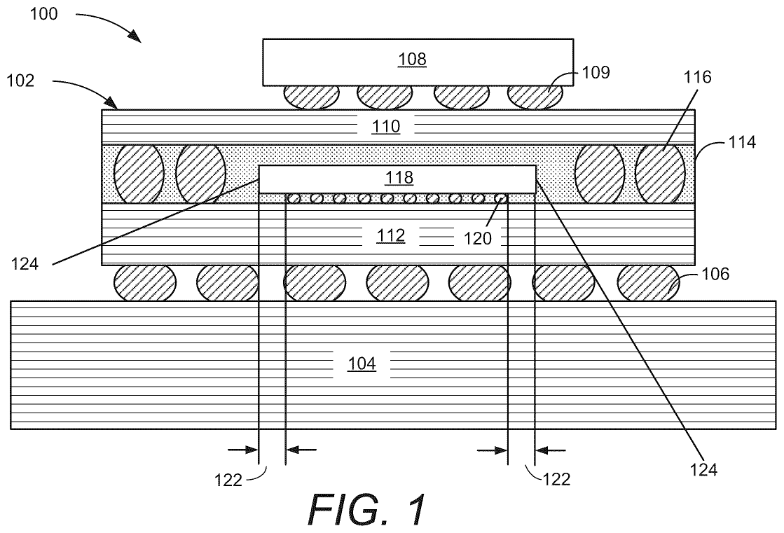

FIG. 1 is a cross-sectional view of an example package-on-package (POP) assembly 100, according to aspects of the disclosure. In this example, the POP assembly 100 includes an electronic package 102 that is mounted to a substrate 104. The electronic package 102 includes contacts 106 (e.g., a ball grid array BGA) that electrically connect the electronic package 102 with contacts and/or metallization structures of the substrate 104. In this example, an integrated circuit package 108 is mounted to the electronic package 102 and includes contacts 109 that electrically connect the electronic components of the integrated circuit package 108 to the electronic package 102.

The example electronic package 102 includes an upper substrate 110 (e.g., interposer) and a lower substrate 112. A dielectric layer 114 is disposed between the lower surface of the upper substrate 110 and the upper surface of the lower substrate 112. One or more via structures 116 extend through the dielectric layer 114 and electrically connect contacts and metallization structures of the upper substrate 110 with contacts and metallization structures of the lower substrate 112. An integrated circuit die is mounted on the upper surface of the lower substrate 112. The integrated circuit dies may be any integrated circuit dies having electronic components that provide electronic functionality for the electronic device in which the electronic package 102 is utilized.

In an aspect, the integrated circuit dies may be a system-on-chip (SOC) die 118 that includes contacts 120 that electrically connect to contacts and metallization structures of the lower substrate 112. In this example, the SOC die 118 includes a keep-out-zone 122 (KOZ) between the contacts 120 and the outer edges 124 of the SOC die 118. In an aspect, the KOZ 121 is a designated area on an integrated circuit die where components, traces, vias, or other elements are restricted to ensure proper electrical, thermal, mechanical, or manufacturing performance.

Certain aspects of the disclosure are implemented with the recognition that regions occupied by KOZ may be employed for other purposes to increase the space efficiency of the electronic package 102. Accordingly, certain aspects of the disclosure include endcap structures that utilize the region occupied by the KOZ to more efficiently use the available space of the electronic package 102. In accordance with aspects of this disclosure, this goal may be accomplished by employing end cap structures at the edges of the SOC die.

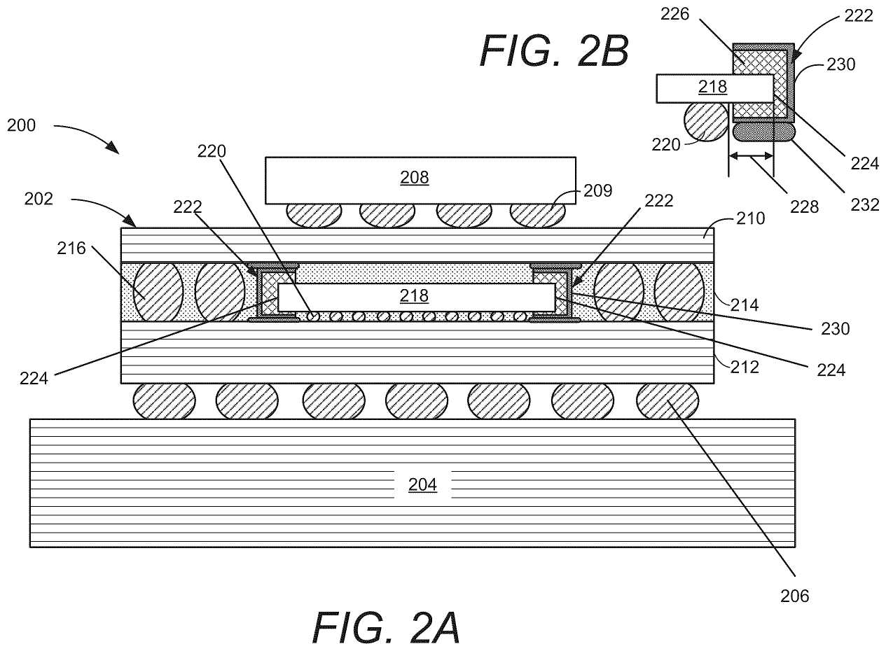

FIG. 2A is a cross-sectional view of a package-on-package assembly 200, according to aspects of the disclosure. In this example, the POP assembly 200 includes an electronic package 202 that is mounted to a substrate 204. The electronic package 202 includes contacts 206 (e.g., a ball grid array BGA) that electrically connect the electronic package 202 with contacts and/or metallization structures of the substrate 204. In this example, an integrated circuit package 208 is mounted to the electronic package 102 and includes contacts 209 that electrically connect the electronic components of the integrated circuit package 208 to the electronic package 202.

The example electronic package 202 includes an upper substrate 210 (e.g., interposer) and a lower substrate 212. A dielectric layer 214 is disposed between the lower surface of the upper substrate 210 and the upper surface of the lower substrate 212. One or more via structures 216 extend through the dielectric layer 214 and electrically connect contacts and metallization structures of the upper substrate 210 with contacts and metallization structures of the lower substrate 212. A die, such as a SOC die 218, may be at least partially embedded in the dielectric layer 214 and include contacts 220 that electrically connect to contacts and metallization structures of the lower substrate 212.

In accordance with aspects of the disclosure, one or more endcap structures 222 are disposed at the outer edges 224 of the SOC die 218. FIG. 2B is a cross-sectional view showing an example endcap structure 222 at an outer edge 224 of the SOC die 218, according to aspects of the disclosure. In this example, the endcap structure 222 includes an inner dielectric layer 226 that is in contact with and extends along at least a portion of the edge 224 of the SOC die 218. As shown, the inner dielectric layer 226 is disposed around the edge 224 and extends into the KOZ 228 of the SOC die 218. The endcap structure 222 also includes a metal layer 230 disposed exterior to the dielectric layer 226. With reference to FIG. 2A, the metal layer 230 provides an electrical connection between the metallization layers of the upper substrate 210 and the metallization layers of the lower substrate 212. According to aspects of the disclosure, the metal layer 230 may be configured to carry signals (e.g., data and/or control signals), power signals (e.g., power voltage and ground connections), etc. In scenarios in which the height of the endcap structure 222 does not span the entire distance between the upper substrate 210 and the lower substrate, an additional metal pad 232 (e.g., a solder paste) may be formed over the upper and/or lower surfaces of the metal layer 230 to make up for the height difference. In an aspect, the pad 232 may extend from the lower outer surface of the metal layer 230 so that the lower surface of the pad 232 is coplanar with the lower edge of the contacts 220.

In accordance with aspects of the disclosure, the endcap structure 222 provides an electrically conductive path between the upper substrate 210 and lower substrate 212 that effectively uses at least a portion of the KOZ 228 to facilitate a greater interconnect density between the substrates 210 and 212 beyond the interconnection provided by via structures 216. Additionally, the endcap structure 222 may facilitate the provision of short interconnect paths and reduce the form factor of a POP package without impacting the structural or signal integrity and power integrity (SIPI) of the POP package.

The electronics of the die 218 and integrated circuit package 208 may cooperate to provide the functionality specified for the electronic package 202. In the foregoing example, the die 218 has been described as a SOC die. However, the die 218 may be any type of electronic circuit die. Similarly, the integrated circuit package 208 may house any type of integrated electronic circuit. In an aspect, the die 218 is a SOC die, while the integrated circuit package 208 houses a dynamic random access memory circuit.

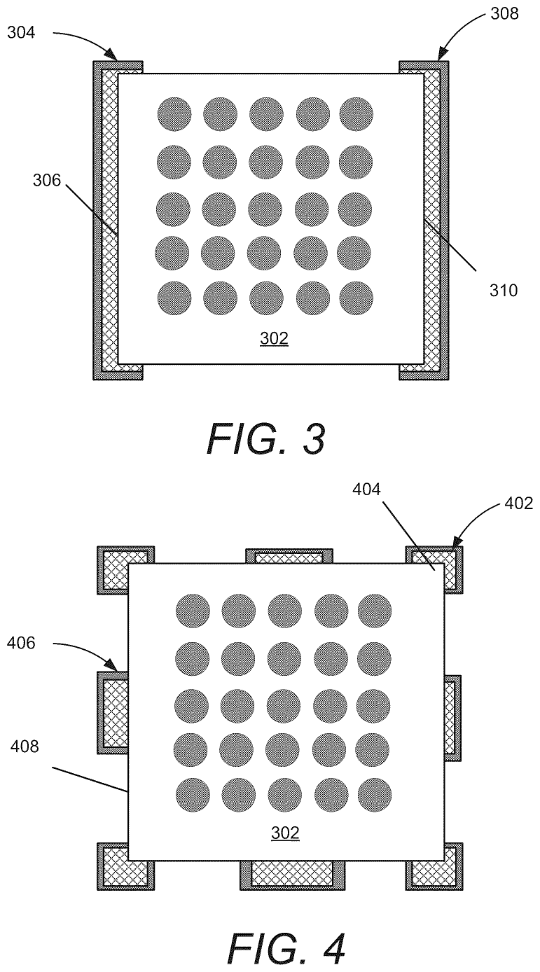

FIG. 3 and FIG. 4 show example engagements between endcap structures and external edges of a die, according to aspects of the disclosure. In both examples, a plurality of endcap structures are disposed about the periphery of a die 302. For simplicity, neither FIG. 3 nor FIG. 4 show the extent to which the dielectric layers of the endcap structures extend over the KOZ of the die 302.

In FIG. 3, a first endcap structure 304 is disposed along a length of a first side edge 306 of the die 302. A second endcap structure 308 disposed along a length of a second edge 310 of the die 302 opposite to the first side edge 306 of the die 302. In an aspect, the configuration of the endcap structures 304 and 308 in FIG. 3 are particularly suitable for carrying power signals (e.g., voltages and/or ground) between the upper and lower substrates of the electronic package. In an aspect, the endcap structures 304 may facilitate electromagnetic interference shielding of the die 302.

In FIG. 4, one or more endcap structures 402 are disposed at one or more corners 404 of the die 302. Additionally, one or more endcap structures 406 are disposed along one or more outer side edges 408 of the die 302. In the example shown in FIG. 4, endcap structures 402 are disposed at each corner 404 of the die 302. Additionally, endcap structures 406 are disposed at each outer side edge 408 of the die 302 in FIG. 4.

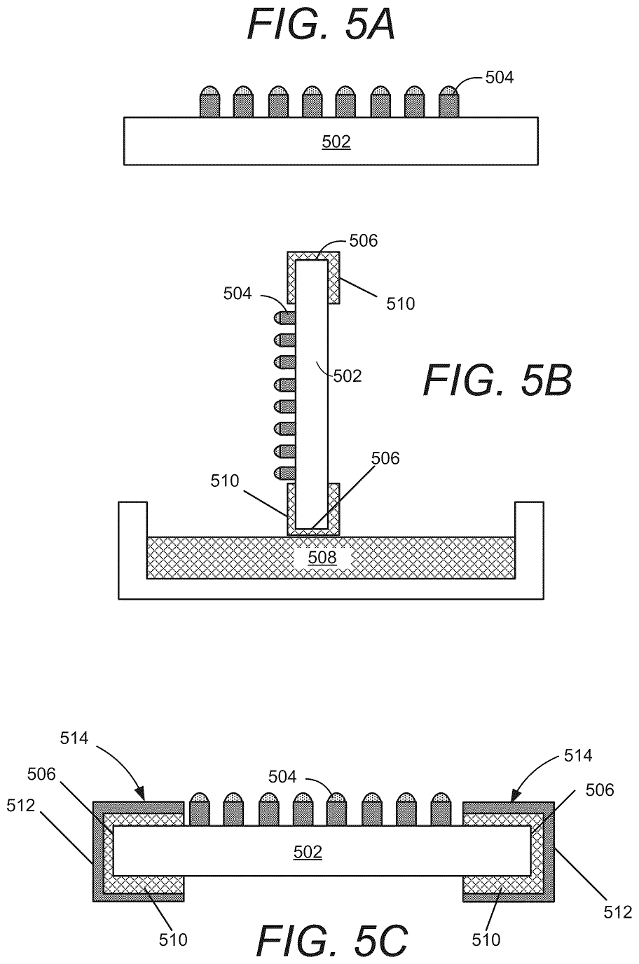

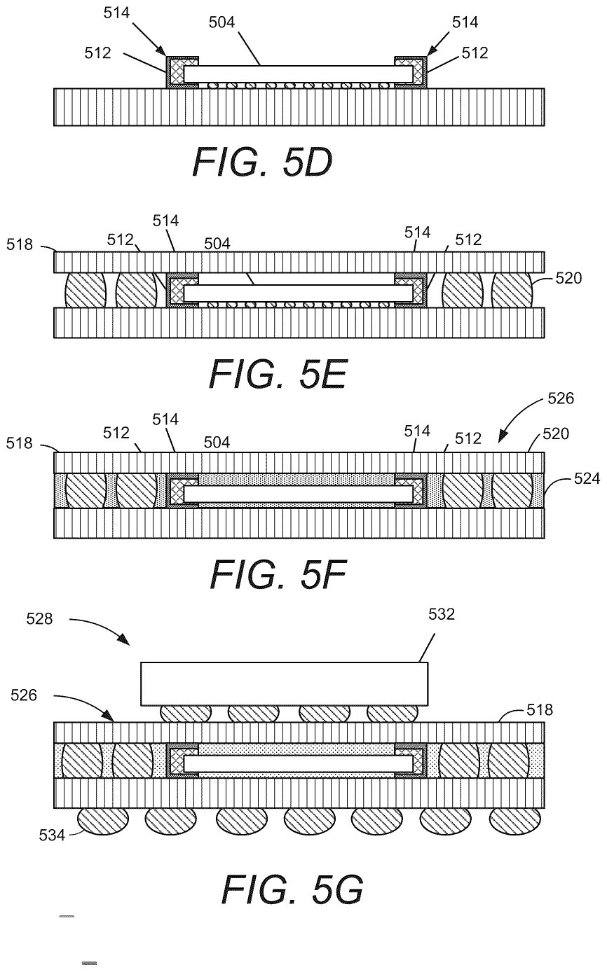

FIG. 5A through FIG. 5G show example operations that may be employed in fabricating a package-on-package assembly that includes an electronic package, according to aspects of the disclosure. FIG. 5A shows a die 502 having bumps 504 that provide electrical connections with the electronic components of the die 502. In FIG. 5A, the die 502 is subject to a bump deposition process along with other dies before it is subject to a die singulation operation that separates the die 502 and corresponding bumps 504 from other dies and their corresponding bumps.

In FIG. 5B, the outer edges 506 of the die 502 may be dipped in a termination ink 508 to form dielectric layers 510. In an aspect, the dielectric layers 510 will ultimately become the interior dielectric layers for the endcap structures at the outer edges 506 of the die 502.

In FIG. 5C, a metal layer 512 is formed over the dielectric layers 510 to complete the fabrication of the endcap structures 514. The metal layer 512 may be formed using any suitable metal deposition process. In an aspect, the metal layers 512 may be deposited using an electroplating technique. In an aspect, the electroplating technique may include depositing a seed layer over the outer surfaces of the dielectric layers 510 using, for example, a chemical vapor deposition (CVD) process followed by an electroplating process. Processes other than electroplating techniques may also be used to deposit the metal layer 512.

In FIG. 5D, the die 502, along with the endcap structures 514, are mounted to an upper surface of a lower substrate 516. The bumps 504 electrically connect the die 502 with contacts and metallization layers of the lower substrate 516. Additionally, the metal layers 512 of the endcap structures 514 are electrically connected to the metallization layers of the lower substrate 516.

In FIG. 5E, an upper substrate 518 is disposed to overlie the die 502 and the endcap structures 514. Here, the metal layers 512 of the endcap structures 514 are electrically connected to metallization structures of the upper substrate 518. Additionally, a plurality of via structures 520 extend between metallization structures of the lower substrate 516 and metallization structures of the upper substrate 518.

In FIG. 5F, a dielectric layer 524 is deposited between the lower surface of the upper substrate 518 and the upper surface of the lower substrate 516. In an aspect, the die 502, bumps 504, endcap structures 514, and the via structures 520 are at least partially embedded in the dielectric layer 524. FIG. 5F shows an example of a finished electronic package 526, according to aspects of the disclosure.

FIG. 5G shows an example package-on-package assembly 528 incorporating the example electronic package 526, according to aspects of the disclosure. In FIG. 5G, an integrated circuit package 530 is mounted to an upper surface of the upper substrate 518 of the electronic package 526. In an aspect, the integrated circuit package 530 includes contacts 532 that provide electrical connections between the components of the integrated circuit package 530 and the metallization structures of the upper substrate 518. Additionally, a plurality of contacts 534 (e.g., a BGA) is formed over a lower surface of the lower substrate 516. The contacts 534 provide electrical connections to the metallization structures of the lower substrate 516 to electrically connect the POP assembly 528 to another substrate (e.g., printed circuit board, another POP structure, etc.).

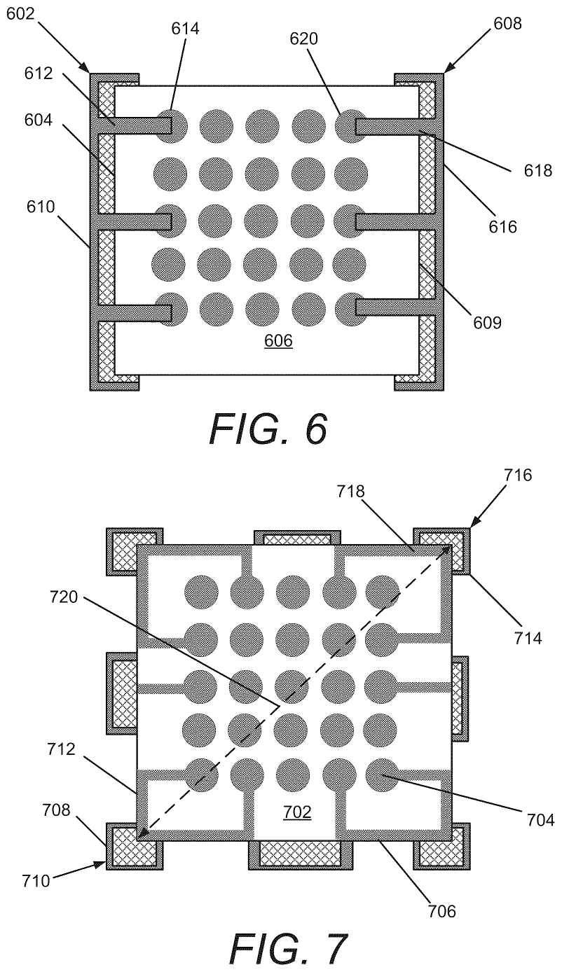

FIG. 6 shows an example arrangement in which endcap structures are electrically connected to contacts at the outer edges of a die, according to aspects of the disclosure. In this example, a first endcap structure 602 engages a first outer edge 604 of a die 606. Additionally, a second endcap structure 608 engages a second outer edge 609 of the die 606. In FIG. 6, the metal layer 610 of the first endcap structure 602 includes one or more conductive extensions 612 that connect the metal layer 610 with one or more contacts 614 of the die 606. Additionally, In FIG. 6, the metal layer 616 of the second endcap structure 608 includes one or more conductive extensions 618 that connect the metal layer 616 with one or more contacts 620 of the die 606. In an aspect, the conductive extensions 612 and 618 may correspond to metal structures of a redistribution layer.

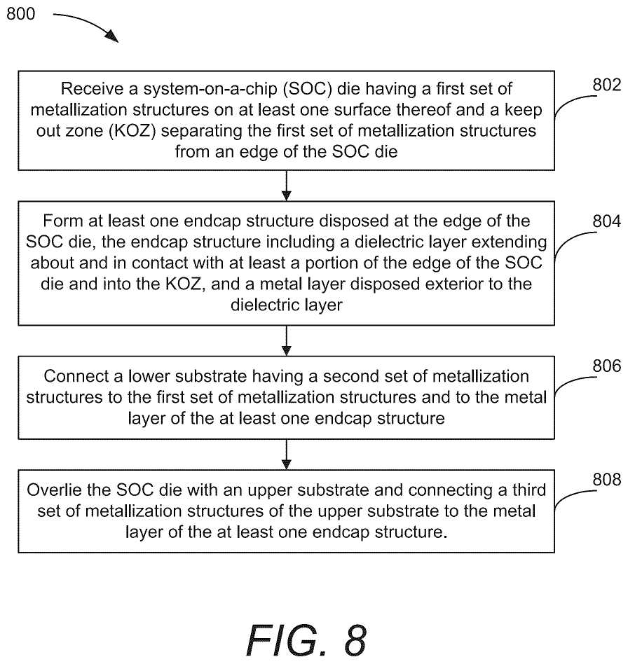

FIG. 7 shows another example arrangement in which endcap structures are electrically connected to contacts at the outer edges of a die, according to aspects of the disclosure. In this example, die 702 includes bumps 704 of a bump layer and conductive lines 706 of a bump distribution layer disposed at the edges of die 702. In accordance with certain aspects of the disclosure, endcap structures may be electrically connected to the conductive lines 706 of the bump distribution layer. In an aspect, the metal layers of certain endcap structures may engage the metallization structures of one or both of the upper substrate and lower substrate of the corresponding electronic package to electrically connect certain conductive lines of the bump distribution layer with one another. Using the arrangement shown in FIG. 7 as an example, the metal layer 708 of endcap structure 710 may be electrically connected to line 712 of the bump distribution layer. Similarly, metal layer 714 of endcap structure 716 may be electrically connected to line 718 of the bump distribution layer. In turn, the metal layers 708 may be connected to metallization structures in the upper substrate and/or lower substrate of the electronic package to electrically connect the conductive lines 712 and 718 of the bump distribution layer with one another. In FIG. 7, an example electrical connection effectively made between the conductive lines 712 and 718 through the endcap structures 710 and 716 is indicated by dotted line 720.

FIG. 8 shows an example method 800 that may be used to fabricate an electronic package, according to aspects of the disclosure. At operation 802, a system-on-chip (SOC) die is received that has a first set of metallization structures on at least one surface thereof and a keep-out-zone (KOZ) separating the first set of metallization structures from an edge of the SOC die. At operation 804, at least one endcap structure is formed that is disposed at the edge of the SOC die. The endcap structure includes a dielectric layer extending about and in contact with at least a portion of the edge of the SOC die and into the KOZ, and a metal layer disposed exterior to the dielectric layer. At operation 806, a lower substrate having a second set of metallization structures is connected to the first set of metallization structures and to the metal layer of the at least one endcap structure. At operation 808, the SOC die is overlaid with an upper substrate and a third set of metallization structures of the upper substrate is connected to the metal layer of the at least one endcap structure.

A technical advantage of the method 800 is that it provides an electronic package having endcap structures at the edges of an SOC die that take advantage of keep-out-zones of the SOC die to optimize the size of the electronic package. Additionally, the endcap structures may facilitate the optimal routing of signals along the shortest path within the electronic package. Still further, the endcap structures may be employed to increase the structural integrity of the mounting and electrical connections of the SOC die within the electronic package.

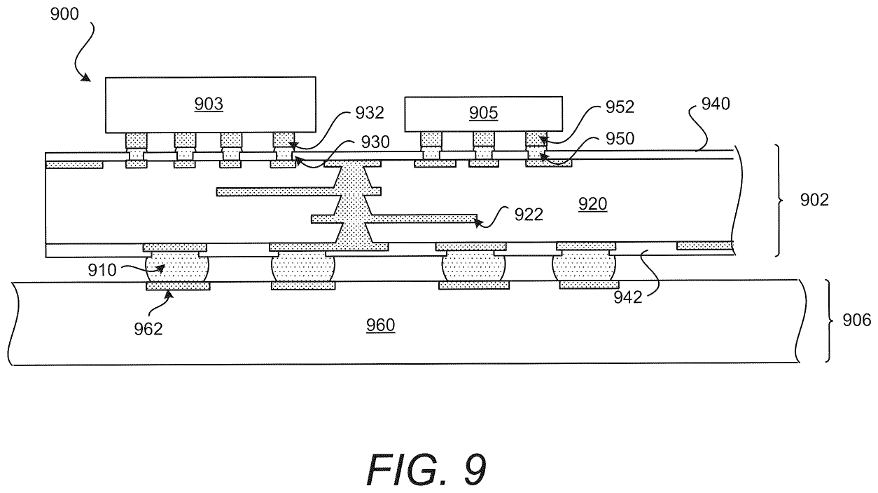

FIG. 9 illustrates a profile view of a package 900 that includes a surface mount substrate 902, an integrated device 903, and an integrated passive device 905, according to aspects of the disclosure. The package 900 may be coupled to a printed circuit board (PCB) 906 through a plurality of solder interconnects 910. The PCB 906 may include at least one board dielectric layer 960 and a plurality of board interconnects 962.

The surface mount substrate 902 includes at least one dielectric layer 920 (e.g., substrate dielectric layer), a plurality of interconnects 922 (e.g., substrate interconnects), a solder resist layer 940 and a solder resist layer 942. The integrated device 903 may be coupled to the surface mount substrate 902 through a plurality of solder interconnects 930. The integrated device 903 may be coupled to the surface mount substrate 902 through a plurality of pillar interconnects 932 and the plurality of solder interconnects 930. The integrated passive device 905 may be coupled to the surface mount substrate 902 through a plurality of solder interconnects 950. The integrated passive device 905 may be coupled to the surface mount substrate 902 through a plurality of pillar interconnects 952 and the plurality of solder interconnects 950.

The package (e.g., 900) may be implemented in a radio frequency (RF) package. The RF package may be a radio frequency front end (RFFE) package. A package (e.g., 900) may be configured to provide Wireless Fidelity (WiFi) communication and/or cellular communication (e.g., 2G, 3G, 4G, 5G). The package (e.g., 900) may be configured to support Global System for Mobile (GSM) Communications, Universal Mobile Telecommunications System (UMTS), and/or Long-Term Evolution (LTE). The package (e.g., 900) may be configured to transmit and receive signals having different frequencies and/or communication protocols.

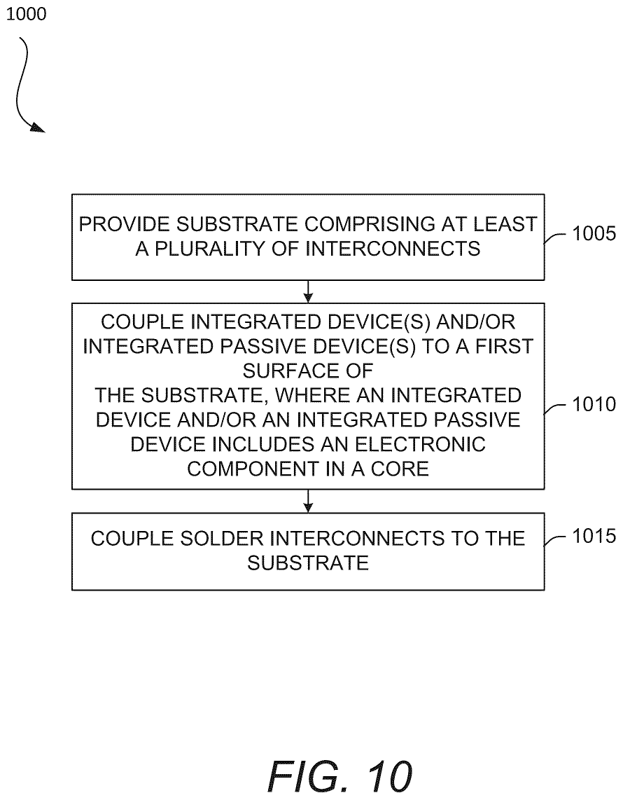

FIG. 10 illustrates an example method 1000 for providing or fabricating a package that includes an integrated device comprising a power splitter, according to aspects of the disclosure. In some implementations, the method 1000 of FIG. 10 may be used to provide or fabricate the package 900 of FIG. 9 described in the disclosure. However, the method 1000 may be used to provide or fabricate any of the packages described in the disclosure.

It should be noted that the method of FIG. 10 may combine one or more processes in order to simplify and/or clarify the method for providing or fabricating a package that includes an integrated device comprising adjacent logic circuits having back-to-back vias, according to aspects of the disclosure. In some implementations, the order of the processes may be changed or modified.

The method provides (at 1005) a substrate (e.g., 902). The substrate 902 may be provided by a supplier or fabricated. The substrate 902 includes at least one dielectric layer 920, and a plurality of interconnects 922. The substrate 902 may include an embedded trace substrate (ETS). In some implementations, the at least one dielectric layer 920 may include prepreg layers.

The method couples (at 1010) at least one integrated device (e.g., 903) to the first surface of the substrate (e.g., 902). For example, the integrated device 903 may be coupled to the substrate 902 through the plurality of pillar interconnects 932 and the plurality of solder interconnects 930. The plurality of pillar interconnects 932 may be optional. The plurality of solder interconnects 930 are coupled to the plurality of interconnects 922. A solder reflow process may be used to couple the integrated device 903 to the plurality of interconnects through the plurality of solder interconnects 930.

The method also couples (at 1010) at least one integrated passive device (e.g., 905) to the first surface of the substrate (e.g., 902). For example, the integrated passive device 905 may be coupled to the substrate 902 through the plurality of pillar interconnects 952 and the plurality of solder interconnects 950. The plurality of pillar interconnects 952 may be optional. The plurality of solder interconnects 950 are coupled to the plurality of interconnects 922. A solder reflow process may be used to couple the integrated passive device 905 to the plurality of interconnects through the plurality of solder interconnects 950.

The method couples (at 1015) a plurality of solder interconnects (e.g., 910) to the second surface of the substrate (e.g., 902). A solder reflow process may be used to couple the plurality of solder interconnects 910 to the substrate.

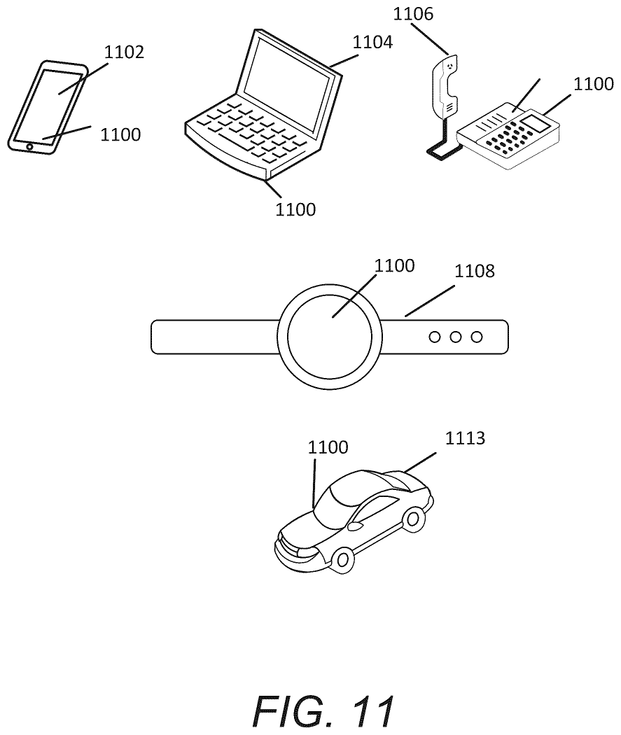

FIG. 11 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (PoP), System in Package (SiP), or System on Chip (SoC). For example, a mobile phone device 1102, a laptop computer device 1104, a fixed location terminal device 1106, a wearable device 1108, or automotive vehicle 1113 may include a device 1100 as described herein. The device 1100 may be, for example, any of the devices and/or integrated circuit (IC) packages described herein. The devices 1102, 1104, 1106 and 1108 and the vehicle 1113 illustrated in FIG. 11 are merely exemplary. Other electronic devices may also feature the device 1100 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:
Aspect 1. An electronic device, comprising: an electronic package comprising a system-on-chip (SOC) die having a first set of metallization structures on at least one surface thereof and a keep-out-zone (KOZ) separating the first set of metallization structures from an edge of the SOC die; at least one endcap structure disposed at the edge of the SOC die, the at least one endcap structure including a dielectric layer extending about and in contact with at least a portion of the edge of the SOC die and into the KOZ, and a metal layer disposed exterior to the dielectric layer; a lower substrate having a second set of metallization structures electrically connected to the first set of metallization structures and to the metal layer of the at least one endcap structure; and an upper substrate overlying the SOC die and having a third set of metallization structures electrically connected to the metal layer of the at least one endcap structure.
Aspect 2. The electronic device of aspect 1, wherein: the electronic package comprises a plurality of endcap structures disposed about a periphery of the SOC die.
Aspect 3. The electronic device of aspect 2, wherein: the first set of metallization structures include a bump layer; and a bump distribution layer disposed at edges of the SOC die and interconnecting a plurality of bumps of the bump layer, wherein at least two of the endcap structures of the plurality of endcap structures interconnect at least two distribution portions of the bump distribution layer.
Aspect 4. The electronic device of any of aspects 1 to 3, wherein: the electronic package comprises a first endcap structure disposed along a length of a first side edge of the SOC die; and a second end structure disposed along a length of a second edge of the SOC die opposite to the first side edge of the SOC die.
Aspect 5. The electronic device of any of aspects 1 to 4, further comprising: an integrated circuit package disposed at an upper surface of the upper substrate and electrically connected to the third set of metallization structures.
Aspect 6. The electronic device of aspect 5, wherein: the integrated circuit package includes a dynamic random access memory.
Aspect 7. The electronic device of any of aspects 1 to 6, further comprising: a dielectric layer extending between an upper surface of the lower substrate and a lower surface of the upper substrate.
Aspect 8. The electronic device of aspect 7, further comprising: one or more via structures extending through the dielectric layer and electrically connecting the second set of metallization structures of the lower substrate with the third set of metallization structures of the upper substrate.
Aspect 9. The electronic device of any of aspects 1 to 8, wherein: the metal layer of the at least one endcap structure is configured to carry power between the second set of metallization structures of the lower substrate and the third set of metallization structures of the upper substrate.
Aspect 10. The electronic device of any of aspects 1 to 9, wherein: the at least one endcap structure is configured to carry electronic signals between the second set of metallization structures of the lower substrate and the third set of metallization structures of the upper substrate.
Aspect 11. The electronic device of any of aspects 1 to 10, wherein the electronic device comprises at least one of: a music player; a video player; an entertainment unit; a navigation device; a communications device; a mobile device; a mobile phone; a smartphone; a personal digital assistant; a fixed location terminal; a tablet computer, a computer; a wearable device; a laptop computer; a server; an internet of things (IoT) device; or a device in an automotive vehicle.
Aspect 12. An electronic package, comprising: a system-on-chip (SOC) die having a first set of metallization structures on at least one surface thereof and a keep-out-zone (KOZ) separating the first set of metallization structures from an edge of the SOC die; at least one endcap structure disposed at the edge of the SOC die, the at least one endcap structure including a dielectric layer extending about and in contact with at least a portion of the edge of the SOC die and into the KOZ, and a metal layer disposed exterior to the dielectric layer; a lower substrate having a second set of metallization structures electrically connected to the first set of metallization structures and to the metal layer of the at least one endcap structure; and an upper substrate overlying the SOC die and having a third set of metallization structures electrically connected to the metal layer of the at least one endcap structure.
Aspect 13. The electronic package of aspect 12, wherein: the electronic package comprises a plurality of endcap structures disposed about a periphery of the SOC die.
Aspect 14. The electronic package of aspect 13, wherein: the first set of metallization structures include a bump layer; and a bump distribution layer disposed at edges of the SOC die and interconnecting a plurality of bumps of the bump layer, wherein at least two of the endcap structures of the plurality of endcap structures interconnect at least two distribution portions of the bump distribution layer.
Aspect 15. The electronic package of any of aspects 12 to 14, wherein: the electronic package comprises a first endcap structure disposed along a length of a first side edge of the SOC die; and a second end structure disposed along a length of a second edge of the SOC die opposite to the first side edge of the SOC die.
Aspect 16. The electronic package of any of aspects 12 to 15, further comprising: an integrated circuit package disposed at an upper surface of the upper substrate and electrically connected to the third set of metallization structures.
Aspect 17. The electronic package of any of aspects 12 to 16, further comprising: a dielectric layer extending between an upper surface of the lower substrate and a lower surface of the upper substrate.
Aspect 18. The electronic package of any of aspects 12 to 17, wherein: the metal layer of the at least one endcap structure is configured to carry power between the second set of metallization structures of the lower substrate and the third set of metallization structures of the upper substrate.
Aspect 19. The electronic package of any of aspects 12 to 18, wherein: the at least one endcap structure is configured to carry electronic signals between the second set of metallization structures of the lower substrate and the third set of metallization structures of the upper substrate.
Aspect 20. A method of fabricating an electronic package, comprising: receiving a system-on-chip (SOC) die having a first set of metallization structures on at least one surface thereof and a keep-out-zone (KOZ) separating the first set of metallization structures from an edge of the SOC die; forming at least one endcap structure disposed at the edge of the SOC die, the endcap structure including a dielectric layer extending about and in contact with at least a portion of the edge of the SOC die and into the KOZ, and a metal layer disposed exterior to the dielectric layer; connecting a lower substrate having a second set of metallization structures to the first set of metallization structures and to the metal layer of the at least one endcap structure; and overlying the SOC die with an upper substrate and connecting a third set of metallization structures of the upper substrate to the metal layer of the at least one endcap structure.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be rerranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device, comprising:
an electronic package comprising
a system-on-chip (SOC) die having a first set of metallization structures on at least one surface thereof and a keep-out-zone (KOZ) separating the first set of metallization structures from an edge of the SOC die;
at least one endcap structure disposed at the edge of the SOC die, the at least one endcap structure including
a dielectric layer extending about and in contact with at least a portion of the edge of the SOC die and into the KOZ, and
a metal layer disposed exterior to the dielectric layer;
a lower substrate having a second set of metallization structures electrically connected to the first set of metallization structures and to the metal layer of the at least one endcap structure; and
an upper substrate overlying the SOC die and having a third set of metallization structures electrically connected to the metal layer of the at least one endcap structure.

2. The electronic device of claim 1, wherein:
the electronic package comprises a plurality of endcap structures disposed about a periphery of the SOC die.

3. The electronic device of claim 2, wherein:
the first set of metallization structures include
a bump layer; and
a bump distribution layer disposed at edges of the SOC die and interconnecting a plurality of bumps of the bump layer, wherein at least two of the endcap structures of the plurality of endcap structures interconnect at least two distribution portions of the bump distribution layer.

4. The electronic device of claim 1, wherein:
the electronic package comprises
a first endcap structure disposed along a length of a first side edge of the SOC die; and
a second end structure disposed along a length of a second edge of the SOC die opposite to the first side edge of the SOC die.

5. The electronic device of claim 1, further comprising:
an integrated circuit package disposed at an upper surface of the upper substrate and electrically connected to the third set of metallization structures.

6. The electronic device of claim 5, wherein:
the integrated circuit package includes a dynamic random access memory.

7. The electronic device of claim 1, further comprising:
a dielectric layer extending between an upper surface of the lower substrate and a lower surface of the upper substrate.

8. The electronic device of claim 7, further comprising:
one or more via structures extending through the dielectric layer and electrically connecting the second set of metallization structures of the lower substrate with the third set of metallization structures of the upper substrate.

9. The electronic device of claim 1, wherein:
the metal layer of the at least one endcap structure is configured to carry power between the second set of metallization structures of the lower substrate and the third set of metallization structures of the upper substrate.

10. The electronic device of claim 1, wherein:
the at least one endcap structure is configured to carry electronic signals between the second set of metallization structures of the lower substrate and the third set of metallization structures of the upper substrate.

11. The electronic device of claim 1, wherein the electronic device comprises at least one of:
a music player;
a video player;
an entertainment unit;
a navigation device;
a communications device;
a mobile device;
a mobile phone;
a smartphone;
a personal digital assistant;
a fixed location terminal;
a tablet computer, a computer;
a wearable device;
a laptop computer;
a server;
an internet of things (IoT) device; or
a device in an automotive vehicle.

12. An electronic package, comprising:
a system-on-chip (SOC) die having a first set of metallization structures on at least one surface thereof and a keep-out-zone (KOZ) separating the first set of metallization structures from an edge of the SOC die;
at least one endcap structure disposed at the edge of the SOC die, the at least one endcap structure including
a dielectric layer extending about and in contact with at least a portion of the edge of the SOC die and into the KOZ, and
a metal layer disposed exterior to the dielectric layer;
a lower substrate having a second set of metallization structures electrically connected to the first set of metallization structures and to the metal layer of the at least one endcap structure; and
an upper substrate overlying the SOC die and having a third set of metallization structures electrically connected to the metal layer of the at least one endcap structure.

13. The electronic package of claim 12, wherein:
the electronic package comprises a plurality of endcap structures disposed about a periphery of the SOC die.

14. The electronic package of claim 13, wherein:
the first set of metallization structures include
a bump layer; and
a bump distribution layer disposed at edges of the SOC die and interconnecting a plurality of bumps of the bump layer, wherein at least two of the endcap structures of the plurality of endcap structures interconnect at least two distribution portions of the bump distribution layer.

15. The electronic package of claim 12, wherein:
the electronic package comprises
a first endcap structure disposed along a length of a first side edge of the SOC die; and
a second end structure disposed along a length of a second edge of the SOC die opposite to the first side edge of the SOC die.

16. The electronic package of claim 12, further comprising:
an integrated circuit package disposed at an upper surface of the upper substrate and electrically connected to the third set of metallization structures.

17. The electronic package of claim 12, further comprising:
a dielectric layer extending between an upper surface of the lower substrate and a lower surface of the upper substrate.

18. The electronic package of claim 12, wherein:
the metal layer of the at least one endcap structure is configured to carry power between the second set of metallization structures of the lower substrate and the third set of metallization structures of the upper substrate.

19. The electronic package of claim 12, wherein:
the at least one endcap structure is configured to carry electronic signals between the second set of metallization structures of the lower substrate and the third set of metallization structures of the upper substrate.

20. A method of fabricating an electronic package, comprising:
receiving a system-on-chip (SOC) die having a first set of metallization structures on at least one surface thereof and a keep-out-zone (KOZ) separating the first set of metallization structures from an edge of the SOC die;
forming at least one endcap structure disposed at the edge of the SOC die, the endcap structure including
a dielectric layer extending about and in contact with at least a portion of the edge of the SOC die and into the KOZ, and
a metal layer disposed exterior to the dielectric layer;
connecting a lower substrate having a second set of metallization structures to the first set of metallization structures and to the metal layer of the at least one endcap structure; and
overlying the SOC die with an upper substrate and connecting a third set of metallization structures of the upper substrate to the metal layer of the at least one endcap structure.
